(19) United States
(12) Patent Application Publication
(10) Pub. No.: US 2019/0187505 A1
(43) Pub. Date: Jun. 20, 2019

(54) THIN FILM TRANSISTOR, CONTROL METHOD THEREFOR, ARRAY SUBSTRATE, AND DISPLAY DEVICE

(71) Applicants: CHONGQING BOE OPTOELECTRONICS TECHNOLOGY CO., LTD., Chongqing (CN); BOE TECHNOLOGY GROUP CO., LTD., Beijing (CN)

(72) Inventors: Wei SHEN, Beijing (CN); Yongliang ZHAO, Beijing (CN); Xu WU, Beijing (CN); Houfeng ZHOU, Beijing (CN); Zhiyong NING, Beijing (CN)

(21) Appl. No.: 16/322,793

(22) PCT Filed: May 10, 2018
(86) PCT No.: PCT/CN2018/086296

§ 371 Date: Feb. 1, 2019

(30) Foreign Application Priority Data
May 27, 2017 (CN) 201710393405.X

(51) Int. Cl. G02F 1/1362; H01L 27/092; H01L 27/12; H01L 29/66; H01L 29/786

(52) U.S. Cl. CPC G02F 1/13624; H01L 27/092; G02F 2001/136245; H01L 29/66742; H01L 29/786; H01L 27/124

(57) ABSTRACT

A thin film transistor, a controlling method thereof, an array substrate and a display device. The thin film transistor includes: a substrate; and a gate electrode, an active layer, a source and a drain on the substrate. The source comprises two source electrodes electrically connected with each other; the drain comprises two drain electrodes electrically connected with each other, and the two drain electrodes are between the two source electrodes; and the active layer comprises primary channels between adjacent source electrodes and drain electrodes and a secondary channel between the two drain electrodes.

### CROSS-REFERENCE TO RELATED APPLICATIONS

The application claims priority to the Chinese patent application No. 201710393405.X, filed on May 27, 2017, the entire disclosure of which is incorporated herein by reference as part of the present application.

### TECHNICAL FIELD

Embodiments of the present disclosure relate to a thin film transistor, a controlling method thereof, an array substrate and a display device.

### BACKGROUND

A thin film transistor liquid crystal display (TFT LCD) mainly comprises a color filter substrate, an array substrate and a liquid crystal layer between the color filter substrate and the array substrate. A deflection of liquid crystal molecules in the liquid crystal layer is controlled by controlling an electric field between a pixel electrode on the array substrate and a common electrode on the color filter substrate, and thereby a desired display effect is achieved. TFT LCDs are widely used due to advantages of high brightness, high contrast, low power consumption, long service life, light weight and so on.

A plurality of thin film transistors (TFTs) are formed on the array substrate, and each liquid crystal molecule in the liquid crystal layer is driven by the TFT integrated behind it. The TFT comprises structures such as a gate, a source and a drain, and when a current is generated in the channel between the source and the drain, the current allows the source and the drain to be conducted, and the TFT starts working.

### SUMMARY

Embodiments of the present disclosure provide a thin film transistor, which is configured that upon a short circuit occurring in either of the primary channels, the drain electrode corresponding to the primary channel where the short circuit occurs is disconnected. The controlling operation has little effect on a performance of the thin film transistor, and the pixel point corresponding to the thin film transistor after the controlling operation can still be used. This method effectively improves a yield of the TFT substrate after maintenance.

An embodiment of the present disclosure provides a thin film transistor, and the thin film transistor includes: a substrate; a gate electrode on the substrate; a gate insulating layer, covering a surface of the gate electrode and a surface of the substrate; an active layer on the gate insulating layer; and a source and a drain on the active layer. The source includes two source electrodes, the drain includes two drain electrodes, and the two drain electrodes are in parallel between the two source electrodes. Primary channels are between adjacent source electrodes and drain electrodes, and a secondary channel is between the two drain electrodes. The primary channels are configured that upon a short circuit occurring, the drain electrode corresponding to the primary channel where the short circuit occurs is disconnected.

For example, width-length ratios of two primary channels between the two source electrodes and the two drain electrodes are identical; and a width-length ratio of the secondary channel is identical to the width-length ratio of either of the primary channels, and a width-length ratio of the thin film transistor after disconnection remains unchanged.

For example, a sum of the width-length ratio of either of the primary channels and the width-length ratio of the secondary channel is larger than the width-length ratio of the other primary channel.

For example, an orthographic projection of the source on the gate electrode partially coincides with the gate electrode.

For example, an orthographic projection of the source on the gate electrode completely coincides with the gate electrode.

For example, the drain is in a U-shaped structure or a dual I-shaped structure; and the source is in a U-shaped structure.

Another embodiment of the present disclosure provides an array substrate, including the above thin film transistor.

Another embodiment of the present disclosure further provides a display device, including the above array substrate.

Another embodiment of the present disclosure further provides a method for controlling the above thin film transistor, and the method includes: detecting whether a short circuit occurs in the primary channels of the thin film transistor; and in a case where a short circuit is detected in one of the primary channels of the thin film transistor, the drain electrode corresponding to the primary channel where the short circuit occurs is disconnected, and the secondary channel between the two drain electrodes is used as a new primary channel.

For example, a sum of a width-length ratio of either of the primary channels and a width-length ratio of the secondary channel is larger than a width-length ratio of the other primary channel.

At least one embodiment of the present disclosure provides a thin film transistor and a controlling method thereof. In the thin film transistor provided by the embodiments of the present disclosure, the source includes two source electrodes, the drain includes two drain electrodes, and the two drain electrodes are in parallel between the two source electrodes. Primary channels are formed between adjacent source electrodes and drain electrodes, and a secondary channel is formed between the two drain electrodes. Upon a short circuit occurring in either of the primary channels, the drain electrode corresponding to the primary channel where the short circuit occurs is disconnected. The disconnected drain electrode is used as a part of the source electrode corresponding to the primary channel where the short circuit occurs, and the secondary channel between the two drain electrodes is used as a new primary channel. The controlling operation has little effect on the performance of the thin film transistor, and the pixel point corresponding to the thin film transistor after the controlling operation can still be used. This method effectively improves the yield of the TFT substrate after maintenance.

In at least one embodiment of the present disclosure, width-length ratios of two primary channels between the two source electrodes and the two drain electrodes are identical, and a width-length ratio of the secondary channel is identical to the width-length ratio of either of the primary channels. With a width-length ratio (W/L) of the TFT switch unchanged, the problematic TFT is repaired, and the defective pixel point is repaired. The performance of the TFT substrate after maintenance remains basically unchanged, and the corresponding pixel point can be normally displayed.

### BRIEF DESCRIPTION OF THE DRAWINGS

In order to clearly illustrate the technical solution of the embodiments of the disclosure, the drawings of the embodiments will be briefly described in the following. It is obvious that the described drawings are only related to some embodiments of the disclosure and thus are not limitative of the disclosure.

FIG. 1 is a structure schematic diagram of a known thin film transistor;

FIG. 2 is a structure schematic diagram of another known thin film transistor;

FIG. 3 is a structure schematic diagram of a thin film transistor provided by the embodiments of the present disclosure;

FIG. 4 is a structure schematic diagram of another thin film transistor provided by the embodiments of the present disclosure; and

FIG. 5 is a flowchart of a method for controlling the thin film transistor illustrated in FIGS. 3 to 4.

Brief description of the drawing symbols: a—drain; b—source; b1—first source electrode; b2—second source electrode; 1—drain; 11—first drain electrode; 12—second drain electrode; 2—source; 21—first source electrode; 22—second source electrode; 3—data line; 4—scanning line; 5—gate electrode; 6—active layer; 100—substrate; 1′—drain; 11′—first drain electrode; 12′—second drain electrode; 2′—source; 21′—first source electrode; 22′—second source electrode; 3′—data line; 4′—scanning line; and 5′—gate electrode.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, “coupled”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

During the process of fabricating the TFT, because of problems such as residues of a channel etching-back process and residues of a process to a channel between the drain and the source, after the fabrication of the TFT, some metal particles or conductive contaminants are still remained in the channels. The conductive residues allow a conductive bridge to be formed between the source and the drain, so as to cause the TFT to dysfunction and not to normally work.

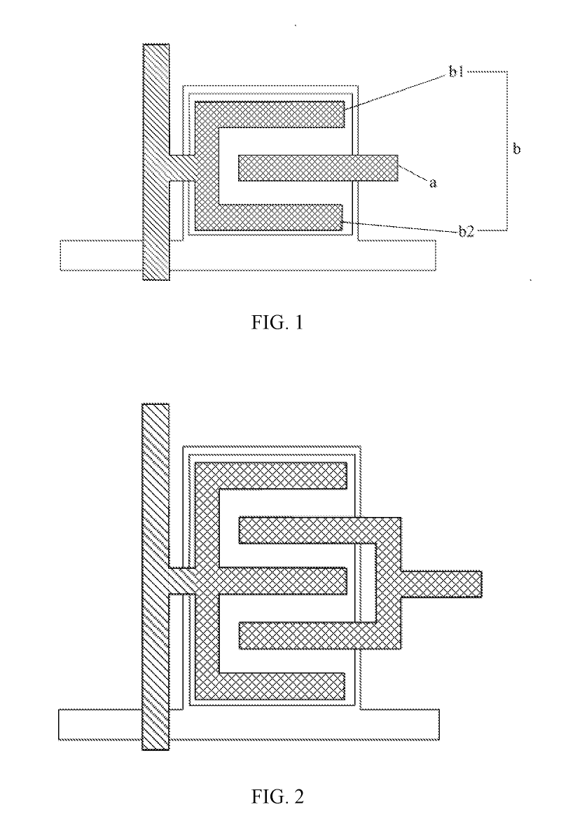

Based on different structures of the channels in TFTs, TFTs can be categorized into a plurality of types, such as TFTs with U-shaped channels. The TFTs with U-shaped channels can be further categorized into a plurality of types, such as the TFT with a single U-shaped channel as illustrated in FIG. 1 and the TFT with dual U-shaped channels as illustrated in FIG. 2, and the TFT with dual U-shaped channels as illustrated in FIG. 2 is a combination of the TFT with the single U-shaped channel as illustrated in FIG. 1. In the TFT with the single U-shaped channel as illustrated in FIG. 1, a indicates a drain, b indicates a source, the source b comprises a first source electrode b1 and a second source electrode b2, a primary channel is formed between the drain a and the first source electrode b1, and another primary channel is formed between the drain a and the second source electrode 112.

The maintenance result of the defective TFT directly influences the final discrimination level of the display device and the yield of the TFT substrate production. For the above TFTs with U-shaped channels, when a U-shaped channel in the TFT is defective, one processing method is to cut off the connection between the source electrode corresponding to the defective channel and the data line, and to allow the TFT to stop working. The pixel point controlled by the TFT is turned off, and the pixel point is rendered a dark point and is not used for display. But when the number of defective pixel points is large, the yield of the TFT substrate after maintenance is greatly reduced.

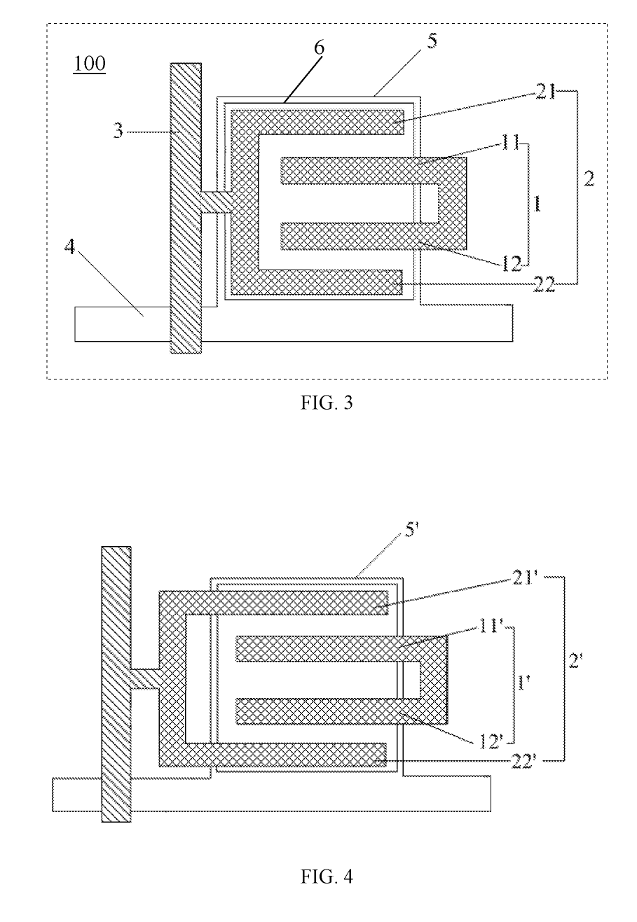

FIG. 3 is a structure schematic diagram of a thin film transistor provided by embodiments of the present disclosure. The thin film transistor illustrated in FIG. 3 includes: a substrate 100, a gate electrode 5, a gate insulating layer, an active layer 6, a drain 1 and a source 2. The gate electrode 5 is disposed on the substrate 100; the gate insulating layer covers a surface of the gate electrode 5 and a surface of the substrate 100; the active layer 6 is disposed on the gate insulating layer; and the drain 1 and the source 2 are disposed on the active layer 6. During a formation of the drain 1 and the source 2, a metal layer is formed on the active layer 6, and then the metal layer is patterned to form the drain 1 and the source 2. Channels are formed between the drain 1 and the source 2 after the patterning process, and the channels are above the gate electrode 5.

The drain 1 includes two drain electrodes: a first drain electrode 11 and a second drain electrode 12; and the source 2 includes two source electrodes: a first source electrode 21 and a second source electrode 22. The two drain electrodes are disposed in parallel between the two source electrodes, primary channels are formed between adjacent source electrodes and drain electrodes, and a secondary channel is formed between the two drain electrodes, that is, in FIG. 3, a primary channel is formed between the first drain electrode 11 and the first source electrode 21, another primary channel is formed between the second drain electrode 12 and the second source electrode 22, and the secondary channel is formed between the first drain electrode 11 and the second drain electrode 12. The primary channels are configured that upon a short circuit occurring, the drain electrode corresponding to the primary channel where the short circuit occurs is disconnected.

When the TFT is in a normal working condition, the two primary channels operate and carriers pass through the two primary channels; and the secondary channel does not operate and no carriers pass through the secondary channel.

When a short circuit occurs in either of the primary channels of the TFT illustrated in FIG. 3, a method for controlling the TFT comprises: disconnecting the drain electrode corresponding to the primary channel where the short circuit occurs, which is specifically cutting off the connection between the drain electrode corresponding to the primary channel where the short circuit occurs and another drain electrode and cutting off the connection between the drain electrode corresponding to the primary channel where the short circuit occurs and the pixel electrode of the TFT display device; and the drain electrode corresponding to the primary channel where the short circuit occurs being used as a part of the source electrode. When the processed TFT operates, the secondary channel between the first drain electrode 11 and the second drain electrode 12 is used as a new primary channel, and cooperates with the remaining another original primary channel.

For example, when a short circuit occurs in the primary channel formed between the first drain electrode 11 and the first source electrode 21, the connection between the first drain electrode 11 and the second drain electrode 12 is cut off, the connection between the first drain electrode 11 and the pixel electrode (not shown) is cut off, and the first drain electrode 11 is used as a part of the first source electrode 21. When the TFT after the process operates, the secondary channel between the first drain electrode 11 and the second drain electrode 12 is used as the new primary channel, and cooperates with the remaining another original primary channel.

Based on the above analysis and compared to the known techniques, the TFT provided by the embodiments of the present disclosure allows the secondary channel between the two drain electrodes to be used as the new primary channel after the controlling operation, therefore width-length ratios of the channels of the TFT after the controlling operation change little, the controlling operation has little effect on the performance of the TFT, and the yield of the production after maintenance is improved.

Realizing the structure design of the TFT provided by the embodiments of the present disclosure does not need to change the manufacturing process. It only needs to change the Mask pattern, and the modification is simple and easy to implement.

FIG. 4 is a structure schematic diagram of another thin film transistor provided by the embodiments of the present disclosure. Compared FIG. 4 with FIG. 3, the relative structures and relative positions of the drain and the source are identical, and the only difference is the relative position of the source and the gate electrode layer. In FIG. 3, the left side of the source 2 is inside the area of the gate electrode 5, and in FIG. 4, the left side of the source 2′ is outside the area of the gate electrode 5′.

As illustrated in FIG. 3, an orthographic projection of the source 2 on the gate electrode 5 completely coincides with the gate electrode 5, and the advantage of this structure is that the size of the gate electrode 5 is large, the channels are completely shielded by the gate electrode 5, and a leakage current of the TFT does not increase abnormally due to illumination. As illustrated in FIG. 4, an orthographic projection of the source 2′ on the gate electrode 5′ partially coincides with the gate electrode 5′, and advantage of this structure is that a width of the gate electrode 5′ is small, and an opening ratio of the TFT is high. The relative position of the source and the gate electrode layer can be set as required.

Because the relative structure and the relative position of the source and the drain of the TFT illustrated in FIG. 4 are identical to those in FIG. 3, when a short circuit occurs in either of the primary channels of the TFT illustrated in FIG. 4, the TFT illustrated in FIG. 4 can be controlled by the above method for controlling the TFT illustrated in FIG. 3. In FIG. 4, 1′ indicates the drain, 11′ indicates the first drain electrode, 12′ indicates the second drain electrode, 2′ indicates the source, 21′ indicates the first source electrode, 3′ indicates the data line, 4′ indicates the scanning line, and 5′ indicates the gate electrode.

The width-length ratios (W/L) of two primary channels of the TFT can be identical or be different, and the width-length ratio of the primary channel and the width-length ratio of the secondary channel can be identical or be different, which can be set according to practical requirements.

In a practical structure, the width-length ratios of two primary channels formed between the two source electrodes and the two drain electrodes can be identical, and the width-length ratio of the secondary channel and the width-length ratio of either of the primary channels can be identical. In the above structure, the width-length ratio of the TFT after the disconnection remains unchanged. With the width-length ratio (W/L) of the TFT switch unchanged, the problematic TFT is repaired, and the defective pixel point is repaired. The performance of the TFT substrate after maintenance remains unchanged, the corresponding pixel point is normally displayed, and the yield of the production after maintenance is improved.

In the practical process of fixing the U-shaped TFT, when a short circuit occurs in one channel, if the TFT is repaired by disconnecting the source corresponding to the channel where the short circuit occurs, the width-length ratio of the channel of the TFT after maintenance is reduced to half, and bad phenomenon can occur to the corresponding pixel point such as appearing too dark, too bright or the like, thereby greatly reducing the performance of the TFT.

In order to ensure the performance of the TFT after maintenance by the method provided by the embodiments of the present disclosure, the width-length ratios of the channels of the TFT after the controlling operation are prevented from being too small, for example, the sum of the width-length ratio of either of the primary channels and the width-length ratio of the secondary channel is larger than the width-length ratio of another primary channel, so that the channels of the TFT after maintenance can still have large width-length ratios, and the TFT can still have a good performance.

The TFT provided by the embodiments of the present disclosure can be applied in a TFT LCD and other display devices comprising a TFT.

According to the structure of the TFT LCD illustrated in FIG. 3, the drain 1 of the TFT can be connected to a pixel electrode of the TFT LCD. The source 2 of the TFT can be connected to a data line 3 of the TFT LCD. The gate electrode 5 of the TFT can be connected to a scanning line 4 of the TFT LCD. In the embodiments of the present disclosure, the drain 1 is in a U-shaped structure or a dual I-shaped structure, and when the drain 1 is in the U-shaped structure, the first drain electrode 11 and the second drain electrode 12 can be two parallel side walls of the U-shaped drain. The drain 1 needs to be connected to the pixel electrode, and if the pixel electrode and the data line 3 are disposed in a same layer, the pixel electrode can be directly connected to the drain 1 without being connected through via holes. In this case, the drain 1 is better in the dual I-shaped structure, and the dual I-shaped structure can increase the opening ratio of the TFT. If the pixel electrode and the data line 3 are not disposed in a same layer, the pixel electrode is connected to the drain 1 through via holes. Because the number of the via holes can be reduced for the U-shaped drain 1, the drain 1 is better in the U-shaped structure, but the opening ratio is relatively lower.

The source 2 can be in a U-shaped structure. As illustrated in FIG. 3 and FIG. 4, the U-shaped drain 2 is disposed inside a U-shaped opening of the U-shaped source 2, and two side walls of the U-shaped drain 1 are respectively parallel to two side walls of the U-shaped source 2. In addition to the above structures, the drain 1 and the source 2 can be in other suitable structures, and the present disclosure is not limited thereto.

The embodiments of the present disclosure further provide an array substrate which includes the thin film transistor provided by the embodiments of the present disclosure.

The embodiments of the present disclosure further provide a display device which includes the array substrate provided by the embodiments of the present disclosure. The display device comprising the above array substrate may be various, such as a liquid crystal display device, a light-emitting diode display device, an organic light-emitting diode display device, or the like.

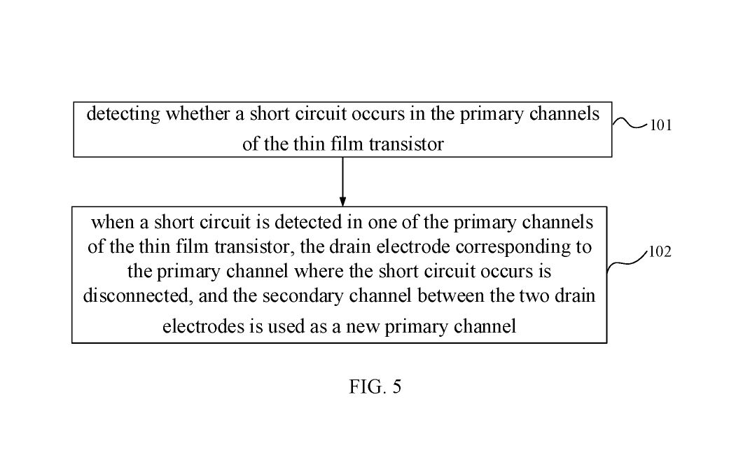

The embodiments of the present disclosure further provide a method for controlling the above thin film transistor. FIG. 5 is a flowchart of a method for controlling the thin film transistor illustrated in FIGS. 3 to 4, and the method for controlling the thin film transistor illustrated in FIG. 5 includes:

Step 101: detecting whether a short circuit occurs in the primary channels of the thin film transistor.

The thin film transistor provided by the embodiments of the present disclosure includes a substrate, a gate electrode, a gate insulating layer, an active layer, a source and a drain, wherein the gate electrode is disposed on the substrate; the gate insulating layer covers a surface of the gate electrode and a surface of the substrate; the active layer is disposed on the gate insulating layer and is disposed above the gate electrode; and the source includes two source electrodes, that is, a first source electrode and a second source electrode; the drain includes two drain electrodes, that is, a first drain electrode and a second drain electrode; the two drain electrodes are disposed in parallel between the two source electrodes, primary channels are formed between adjacent source electrodes and drain electrodes, and a secondary channel is formed between the two drain electrodes.

When the TFT is in a normal working condition, the two primary channels operate and carriers pass through the two primary channels; and the secondary channel does not operate and no carriers pass through the secondary channel.

During the process of fabricating the TFT, because of problems such as residues of the channel etching process and residues of channel process between the source and the drain, after the fabrication of the TFT, some metal particles or conductive contaminants are still remained in the channels. The conductive residues allow a conductive bridge to be formed between the source and the drain, so as to cause the TFT to dysfunction and not to work normally.

Therefore, when the TFT has a problem and cannot normally operate, it is available to detect whether a short circuit occurs in the primary channels of the TFT when repairing and dealing with the TFT. There are various methods for detecting where a short circuit occurs in the primary channels, for example, an automatic pattern detecting method which is to determine a position of the short circuit by contrasting a gray scale through lens scanning; or an electrical detecting method which is to determine a position of the short circuit by determining the short-circuited pixel where an abnormality occurs in the simulation display after an electrical signal is applied.

Step 102: when a short circuit is detected in one of the primary channels of the thin film transistor, the drain electrode corresponding to the primary channel where the short circuit occurs is disconnected, and the secondary channel between the two drain electrodes is used as a new primary channel.

When a short circuit is detected in one of the primary channels of the TFT, a method for controlling the TFT comprises: disconnecting the drain electrode corresponding to the primary channel where the short circuit occurs, which is specifically cutting off the connection between the drain electrode corresponding to the primary channel where the short circuit occurs and another drain electrode, and cutting off the connection between the drain electrode corresponding to the primary channel where the short circuit occurs and the pixel electrode of the TFT display device; and the drain electrode corresponding to the primary channel where the short circuit occurs being used as a part of the source electrode. When the processed TFT operates, the secondary channel between the two drain electrodes is used as the new primary channel, and cooperates with the remaining another original primary channel.

Compared to the known art, because the secondary channel between the two drain electrodes is used as the new primary channel after the TFT provided by the embodiments of the present disclosure is controlled, the controlling operation has little effect on the performance of the TFT, and the TFT after maintenance and the corresponding pixel point can still operate.

The embodiments of the present disclosure provide a thin film transistor and a controlling method thereof. In the thin film transistor provided by the embodiments of the present disclosure, the source includes two source electrodes, the drain includes two drain electrodes, and the two drain electrodes are disposed in parallel between the two source electrodes. Primary channels are formed between adjacent source electrodes and drain electrodes, and a secondary channel is formed between the two drain electrodes. Upon a short circuit occurring in either of the primary channels, the drain electrode corresponding to the primary channel where the short circuit occurs is disconnected. The disconnected drain electrode is used as a part of the source electrode corresponding to the primary channel where the short circuit occurs, and the secondary channel formed between the two drain electrodes is used as a new primary channel. The controlling operation has little effect on the performance of the thin film transistor, and the pixel point corresponding to the thin film transistor after the controlling operation can still be used. This method effectively improves the yield of the TFT substrate after maintenance.

In the embodiments of the present disclosure, width-length ratios of two primary channels formed between the two source electrodes and the two drain electrodes are identical, and a width-length ratio of the secondary channel is identical to the width-length ratio of either of the primary channels. In a case where a width-length ratio (W/L) of the TFT switch remains unchanged, the problematic TFT is repaired, and the defective pixel point is repaired. The performance of the TFT substrate after maintenance remains basically unchanged, and the corresponding pixel point ca be normally displayed.

Each embodiment in the present specification is described in a progressive manner, each embodiment is focused on different points from other embodiments, and same or similar parts between each embodiment can be referred to each other.

What have been described above are only specific implementations of the present disclosure, the protection scope of the present disclosure is not limited thereto, and the protection scope of the present disclosure should be based on the protection scope of the claims.

1. A thin film transistor, comprising:
a substrate; and
a gate electrode, an active layer, a source and a drain on the substrate,
wherein the source comprises two source electrodes electrically connected with each other;
the drain comprises two drain electrodes electrically connected with each other, and the two drain electrodes are between the two source electrodes; and
the active layer comprises primary channels between adjacent source electrodes and drain electrodes, and a secondary channel between the two drain electrodes.

2. The thin film transistor according to claim 1, wherein width-length ratios of two primary channels are identical and are further identical to a width-length ratio of the secondary channel.

3. The thin film transistor according to claim 1, wherein a sum of the width-length ratio of either of the primary channels and the width-length ratio of the secondary channel is larger than the width-length ratio of the other primary channel.

4. The thin film transistor according to claim 1, wherein an orthographic projection of the two source electrodes on the substrate partially coincides with an orthographic projection of the gate electrode on the substrate.

5. The thin film transistor according to claim 1, wherein an orthographic projection of the two source electrodes on the substrate is within an orthographic projection of the gate electrode on the substrate.

6. The thin film transistor according to claim 1, wherein the drain is in a U-shaped structure or a dual I-shaped structure: and
the source is in a U-shaped structure.

7. An array substrate, comprising the thin film transistor

8. A display device, comprising the array substrate according to claim 7.

9. A method for controlling the thin film transistor according to claim 1, comprising:
detecting whether a short circuit occurs in the primary channels of the thin film transistor; and
in a case where a short circuit is detected in one of the primary channels, the drain electrode corresponding to the primary channel where the short circuit occurs is disconnected to allow the secondary channel to function as a new primary channel of the thin film transistor after the disconnection

10. The controlling method according to claim 9, wherein the drain electrode corresponding to the primary channel where the short circuit occurs functions as a part of a source of the thin film transistor after the disconnection.

11. The thin film transistor according to claim 1, wherein the active layer is at a side of the gate electrode away from the substrate, and the source and the drain are in a same layer at a side of the active layer away from the substrate.

12. The thin film transistor according to claim 1, wherein the two drain electrodes are parallel to each other.

13. The thin film transistor according to claim 12, wherein the two source electrodes are parallel to each other and further parallel to the two drain electrodes.

14. The thin film transistor according to claim 2, wherein an orthographic projection of the two source electrodes on the substrate partially coincides with an orthographic projection of the gate electrode on the substrate.

15. The thin film transistor according to claim 3, wherein an orthographic projection of the two source electrodes on the substrate partially coincides with an orthographic projection of the gate electrode on the substrate.

16. The thin film transistor according to claim 11, wherein an orthographic projection of the two source electrodes on the substrate partially coincides with an orthographic projection of the gate electrode on the substrate.

17. The thin film transistor according to claim 12, wherein an orthographic projection of the two source electrodes on the substrate partially coincides with an orthographic projection of the gate electrode on the substrate.

18. The thin film transistor according to claim 13, wherein an orthographic projection of the two source electrodes on the substrate partially coincides with an orthographic projection of the gate electrode on the substrate.

19. The array substrate according to claim 7, further comprising a data line and a pixel electrode, wherein the data line is electrically connected with the source of the thin film transistor, and the pixel electrode is electrically connected with the drain of the thin film transistor.

20. A thin film transistor, comprising a substrate, and a gate electrode, a source and a drain on the substrate,
wherein the source comprises two source electrodes electrically connected with each other;
the drain comprises two drain electrodes disconnected with each other, and the two drain electrodes are between the two source electrodes; and
a short circuit is between the source and one of the two drain electrodes.
